(19) United States
(12) Patent Application Publication
(10) Pub. No.: US 2009/0098729 A1
(43) Pub. Date: Apr. 16, 2009

(54) METHOD FOR MANUFACTURING A SEMICONDUCTOR DEVICE

(76) Inventor: Jeong-Yel Jang, Eumseong-gun (KR)

Correspondence Address: SHERR & VAUGHN, PLLC, 620 HERNDON PARKWAY, SUITE 200, HERNDON, VA, 20170, US

(21) Appl. No.: 12/249,108

(22) Filed: Oct. 10, 2008

(30) Foreign Application Priority Data
Oct. 15, 2007 (KR) 10-2007-0103369

(51) Int. Cl. H01L 21/4763

(52) U.S. Cl. 438/637; 257/E21.585

(57) ABSTRACT

A method for manufacturing a semiconductor device includes that can prevent formation of fences of reaction by-products around chain holes during a dual damascene process, so subsequent metal gap fill defects are prevented, making it possible to prevent device failure. The method may include forming a via hole in an interlayer insulating layer exposing a bottom anti-reflection coating, and then filling the via hole with a first material, and then removing a portion of the first material, and then forming an oxide film over the first material to refill the via hole, and then forming a trench by etching the interlayer insulating layer and the oxide film, and then opening the via hole by removing the first material in the via hole to the bottom anti-reflection coating, and then etching the bottom anti-reflection coating to expose the metal wire, and then filling the opened via hole and trench with metal.

The present application claims priority under 35 U.S.C. §119 to Korean Patent Application No. 10-2007-0103369 (filed on Oct. 15, 2008), which is hereby incorporated by reference in its entirety.

### BACKGROUND

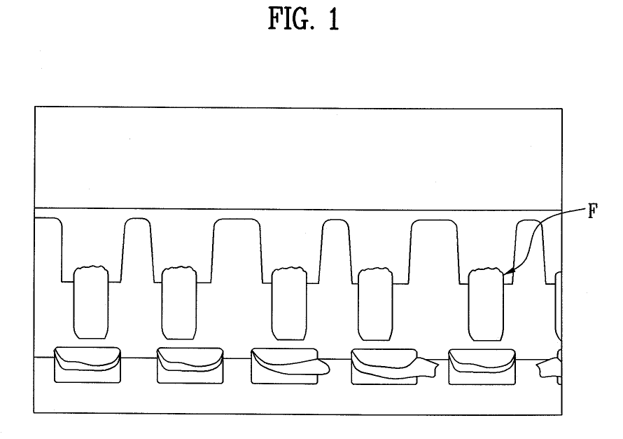

In developing logic products of 130 nm or less, a dual damascene process, in which copper with low electric conductivity and resistance is used as a wire material, has been mostly applied to a back end of line (BEOL) process. In the dual damascene process, there is a via first method to etch a via hole and then form a trench line. When the dual damascene is formed using the via first method, the inside of the via hole is filled with the same material as a bottom anti-reflection coating (BARC) film in order to prevent a lower metal from opening when the trench line is formed after the via hole is etched. Thereafter, a process for forming a trench pattern is performed in a state that a predetermined amount of the BARC film remains in the via hole through a recess process. The trench etch process uses a low-k material which includes a lot of carbon in order to lower the k value, such that the low-k material reacts with the etching gas to generate a great amount of reaction by-products. As oxide-based IMD material and material filled in the via hole are etched simultaneously, different materials are etched simultaneously to cause differences between the generated reaction by-products. As illustrated in example FIG. 1, this results in the generation of circle-shaped fences F, in which oxide remains around the via hole. The fences prevent the inside of the via hole from being filled with metal in the following process, thereby causing metal gap fill defects.

### SUMMARY

Embodiments relate to a method for manufacturing a semiconductor device which prevents generation of fence defects when a dual damascene process according to a via first method is performed.

Embodiments relate to a method for manufacturing a semiconductor device that may include at least one of the following: forming an interlayer insulating layer on and/or over a substrate; and then forming a via hole by etching the interlayer insulating layer; and then filling the via hole with a first material; and then removing a portion of the first material; and then filling the via hole on and/or over the remaining first material with an oxide film; and then forming a trench photoresist pattern on and/or over the substrate filled with the oxide film; and then forming a trench line by etching the interlayer insulating layer and the oxide film using the trench photoresist pattern using an etching mask; and then opening the via hole by removing the first material filled in the via hole; and then filling the opened via hole and trench line with metal.

Embodiments relate to a method that may include at least one of the following: forming a lower wire over a substrate; and then forming a bottom anti-reflection coating over the substrate including the lower wire; and then forming a first oxide film over the substrate including the bottom anti-reflection coating; and then forming a via hole in the first oxide film to expose a portion of the bottom anti-reflection coating; and then filling the via hole with a first material; and then removing a portion of the first material to a predetermined level; and then forming a second oxide layer having a void over the first material to refill the via hole; and then forming a trench exposing first material; and then removing the first material from the via hole; and then forming a metal layer in the via hole and the trench.

Embodiments relate to a method that may include at least one of the following: forming a lower metal wire over a substrate; and then forming a first bottom anti-reflection coating over the lower wire; and then forming a first oxide layer over the first bottom anti-reflection coating; and then forming a first photoresist pattern over the first oxide layer; and then forming a via hole exposing the first bottom anti-reflection coating by performing a first etching process on the first oxide layer using the first photoresist pattern as a mask and then removing the first photoresist pattern; and then filling the via hole with one of a photoresist and a second bottom anti-reflection coating; and then removing a portion of the one of photoresist and the second bottom anti-reflection coating; and then refilling the via hole by forming a second oxide layer having a void over the one of photoresist and the second bottom anti-reflection coating; and then forming a second photoresist pattern over the second oxide layer; and then forming a trench exposing the one of the photoresist and the second bottom anti-reflection coating by performing a second etching process on the first oxide layer and the second oxide layer using the second photoresist pattern as an etching mask and then removing the second photoresist pattern; and then removing the one of photoresist and the second bottom anti-reflection coating from the via hole; and then exposing the lower metal wire by performing a third etching process on the first bottom anti-reflection coating; and then forming a metal layer in the via hole and the trench

### DRAWINGS

Example FIG. 1 illustrates a semiconductor device.

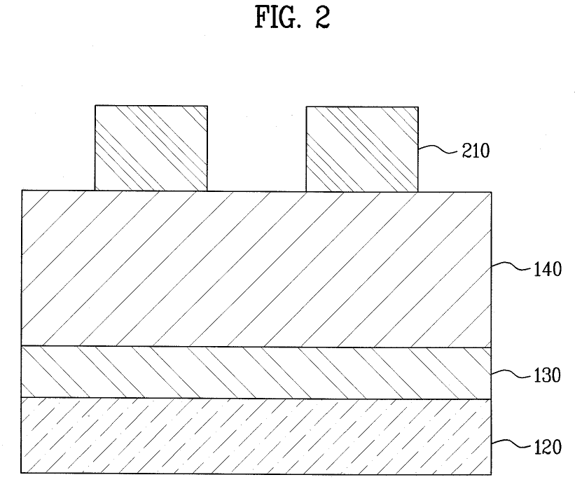

Example FIGS. 2 to 8 illustrate a method for manufacturing a semiconductor device in accordance with embodiments.

### DESCRIPTION

Reference will now be made in detail to embodiments, examples of which are illustrated in the accompanying example drawing figures. Wherever possible, the same reference numbers will be used throughout the example drawing figures to refer to the same or like parts.

As illustrated in example FIG. 2, lower wire 120 may be formed on and/or over or in a substrate. While embodiments illustrate a metal wire connected to the lower wire 120, the metal wire is not limited thereto. For example, the metal wire of the dual damascene in accordance with embodiments may be connected to source, drain or gate. Bottom anti-reflection coating (BARC) 130 may be formed on and/or over the substrate including lower wire. Bottom anti-reflection coating 130 may be formed of SiC, SiN or the like. Interlayer insulating layer 140 is then formed on and/or over the substrate either directly or on and/or over BARC 130. Interlayer insulating layer 140 may be formed of an oxide material such as phospho-silicate-glass (PSG), boron-silicate-glass (BSG), boron-phosphoros-ailicate-glass (BPSG) and the like. Via photoresist film pattern 210 is then formed on and/or over interlayer insulating layer 140.

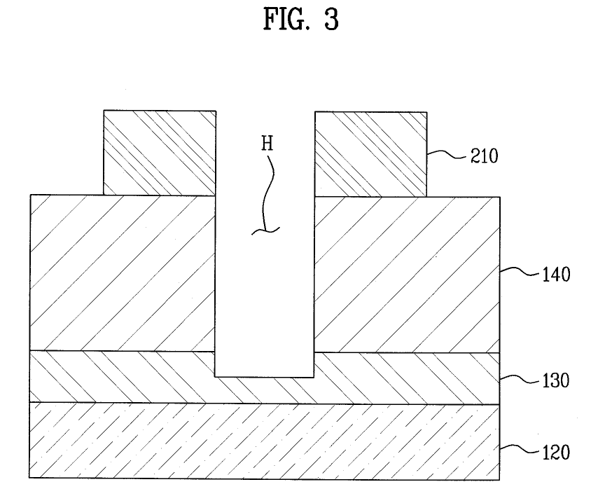

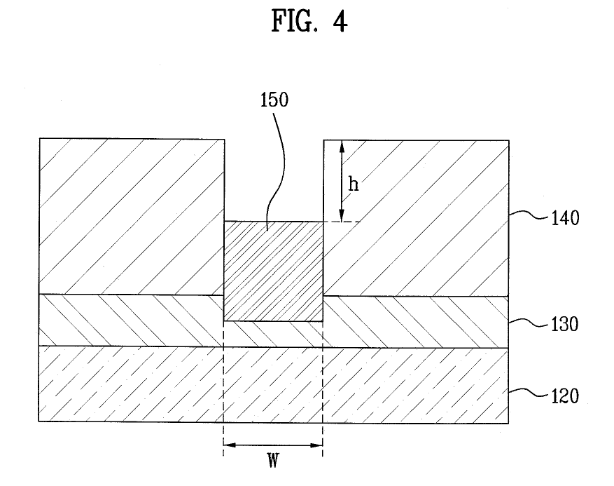

As illustrated in example FIGS. 3 and 4, interlayer insulating layer 140 is etched using via photoresist pattern 210 as an etching mask to form via hole H. Etching of lower wire 120 is prevented due to bottom anti-reflection coating 130. Via photoresist pattern 210 is removed and then via hole H is filled with first material 150. First material 150 is provided to prevent exposing the surface of lower wire 120 during a subsequent etching process to form trench line T. Via hole H may be filled with first material 150 composed of the same material as bottom anti-reflection coating (BARC) film 130. First material 150 may be composed of a photoresist (PR) material. A portion of first material 150 is then selectively removed to ensure that the uppermost surface of first material 150 remains below at least ½ of the depth of via hole H.

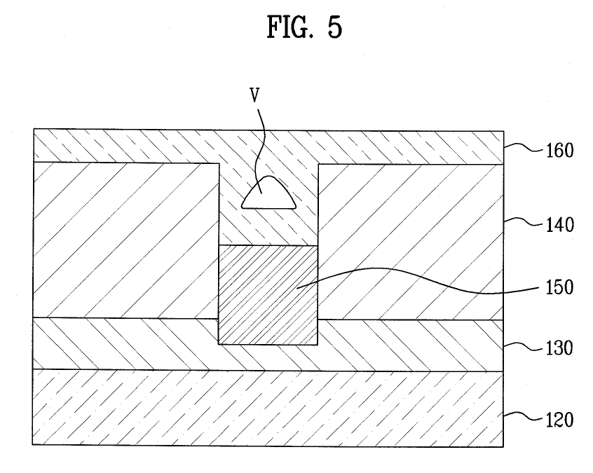

As illustrated in example FIG. 5, via hole H is filled with oxide film 160 so that it is on and/or on the remaining first material 150. Oxide film 160 may be composed of a low temperature oxide (LTO). Oxide film may be composed of the same material as interlayer insulating layer 140. Oxide film 160 may include one or more void V. When via hole H is filled with oxide film 160, the depth of via hole H filled with first material 150 may be controlled in order that an over hang is caused to allow oxide film 160 to include the void. Particularly, via hole H may be filled with first material 150 so that the aspect ratio of the depth h to the width w, is in a range between approximately 2:1 to 5:1. For example, when via hole H on and/or over remaining first material 150 is filled with oxide film 160, the width w of via hole H becomes below 150 nm, so that oxide film 160 can include void V. The width of via hole H is in a range between approximately 150 nm to 10 nm, so that the oxide film can include void V. The width of the via hole is not limited thereto.

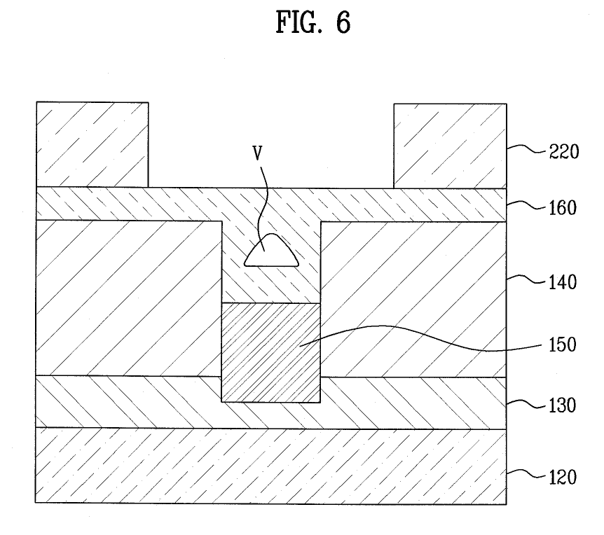

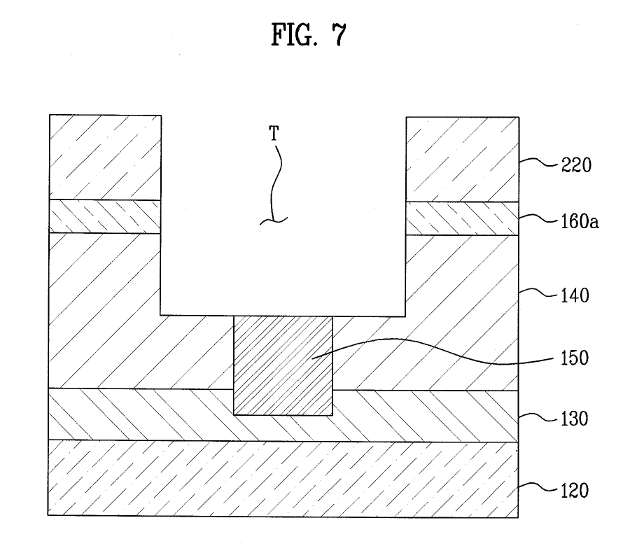

As illustrated in example FIGS. 6 and 7, trench photoresist pattern 220 is formed on and/or over the substrate including oxide film 160. Interlayer insulating layer 140 and oxide film 160 are etched using trench photoresist pattern 220 as an etching mask to form trench line T. Although an etching is performed until first material 150 is exposed, only interlayer insulating layer 140 and oxide film 160 are etched, but first material 150 is not etched. Since first material 150 has been already recessed by ½ or less of the via hole H height, there is no need to further etch first material 150.

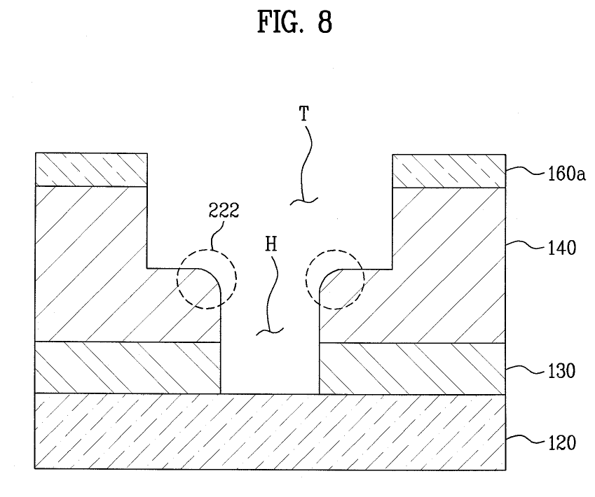

As illustrated in example FIG. 8, first material 150 filled in via hole H is removed to open via hole H. Bottom anti-reflection coating 130 is then selectively etched to expose lower wire 120. Thereafter, the opened via hole H and trench line T are filled with metal, so that a metal wire may be formed by means of a dual damascene. Oxide film 160a remaining on and/or over interlayer insulating layer 140 may be removed or instead may remain thereon and/or thereover.

With a method for manufacturing a semiconductor device in accordance with embodiments, a via hole is filled with bottom anti-reflection coating (BARC) material or photoresist (PR) material after a via hole is formed and then the via hole is recessed by ½ or more of its depth. Thereafter, an oxide film such as a low temperature oxide (LTO) is deposited in the via hole. The width of the via hole is 150 nm or less, so that the inside of the via hole is completely filled with the LTO film such that the LTO film is formed on and/or over the uppermost surface of the interlayer insulating layer, thereby forming one or more voids in the LTO film. Etching gas thereby etches only the interlayer layer and the LTO while a trench etching is performed, not forming fences around the via hole. Because the LTO has a void, the amount of reaction by-products is reduced when etching the interlayer insulating film and the LTO film to form the trench line. Also, since the LTO has a void, when forming the trench line, a corner edge 222 of the trench line is formed having a round cross-section, making it possible to more prevent the via hole from forming fences. Accordingly, the method for manufacturing a semiconductor device in accordance with embodiments prevents fences of reaction by-products formed around chain holes during a dual damascene process, so subsequent metal gap fill defects are prevented, making it possible to prevent device failure.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a lower metal wire over a substrate; and then
forming a first bottom anti-reflection coating over the lower wire; and then
forming a first oxide layer over the first bottom anti-reflection coating; and then
forming a first photoresist pattern over the first oxide layer; and then
forming a via hole exposing the first bottom anti-reflection coating by performing a first etching process on the first oxide layer using the first photoresist pattern as a mask and then removing the first photoresist pattern; and then
filling the via hole with one of a photoresist and a second bottom anti-reflection coating; and then
removing a portion of the one of photoresist and the second bottom anti-reflection coating; and then
refilling the via hole by forming a second oxide layer having a void over the one of photoresist and the second bottom anti-reflection coating; and then
forming a second photoresist pattern over the second oxide layer; and then
forming a trench exposing the one of the photoresist and the second bottom anti-reflection coating by performing a second etching process on the first oxide layer and the second oxide layer using the second photoresist pattern as an etching mask and then removing the second photoresist pattern; and then
removing the one of photoresist and the second bottom anti-reflection coating from the via hole; and then
exposing the lower metal wire by performing a third etching process on the first bottom anti-reflection coating; and then
forming a metal layer in the via hole and the trench.

2. A method for manufacturing a semiconductor device comprising:
forming a metal wire over a substrate; and then
forming a bottom anti-reflection coating over the substrate including the lower wire; and then
forming an interlayer insulating layer over the substrate including the bottom anti-reflection coating; and then
forming a via hole by etching the interlayer insulating layer and a portion of the bottom anti-reflection coating; and then
filling the via hole with a first material; and then
removing a portion of the first material; and then
forming an oxide film over the first material to refill the via hole; and then
forming a photoresist pattern over the substrate; and then
forming a trench by etching the interlayer insulating layer and the oxide film using the photoresist pattern as an etching mask; and then
opening the via hole by removing the first material in the via hole to expose a portion of the bottom anti-reflection coating; and then
etching the bottom anti-reflection coating to expose the metal wire; and then
filling the opened via hole and trench with metal.

3. The method of claim 2, wherein the oxide film includes a void.

4. The method of claim 3, wherein the aspect ratio of the depth to the width of the via hole over the first material is in a range between approximately 2:1 to 5:1 after removing the portion of the first material.

5. The method of claim 4, wherein the width of the via hole on the remaining first material is in a range between approximately 150 nm to 10 nm.

6. The method of claim 2, wherein during forming the trench, the first material is not etched.

7. The method of claim 2, wherein the first material comprises a bottom anti-reflection coating.

8. The method of claim 2, wherein the first material comprises a photoresist material.

9. The method of claim 2, wherein the oxide film comprises a low temperature oxide.

10. The method of claim 2, wherein the first material is selectively removed so that the first material remains at a level at least ½ of the depth of the via hole.

11. A method comprising:
forming a lower metal wire over a substrate; and then
forming a bottom anti-reflection coating over the substrate including the lower metal wire; and then
forming a first oxide film over the substrate including the bottom anti-reflection coating; and then
forming a via hole in the first oxide film to expose the bottom anti-reflection coating; and then
filling the via hole with a first material; and then
removing a portion of the first material to a predetermined level; and then
forming a second oxide layer having a void over the first material to refill the via hole; and then
forming a trench exposing first material; and then
removing the first material from the via hole to expose the bottom anti-reflection coating; and then
etching the bottom anti-reflection coating to expose the lower metal wire; and then
forming a metal layer in the via hole and the trench.

12. The method of claim 11, wherein the bottom anti-reflection coating comprises one of SiC and SiN.

13. The method of claim 11, wherein the first oxide and the second oxide each comprise one of phospho-silicate-glass (PSG), boron-silicate-glass (BSG) and boron-phosphoros-ailicate-glass (BPSG).

14. The method of claim 11, wherein forming the via hole comprises:
forming a photoresist pattern over the interlayer insulating layer; and then
etching a portion of the interlayer insulating layer using the photoresist pattern as a mask; and then
removing the photoresist pattern.

15. The method of claim 11, wherein forming the trench comprises:
forming a photoresist pattern over the second oxide layer; and then
etching the first oxide layer and the second oxide layer using the photoresist pattern as an etching mask; and then
removing the photoresist pattern.

16. The method of claim 11, wherein the first material is not etched when etching the first oxide layer and the second oxide layer.

17. The method of claim 11, wherein the oxide film comprises a low temperature oxide.

18. The method of claim 11, wherein the predetermined level is at least ½ of the depth of the via hole.

19. The method of claim 11, wherein the first material comprises a second bottom anti-reflection coating.

20. The method of claim 11, wherein the first material comprises a photoresist material.
